(19) United States
(12) Patent Application Publication
(10) Pub. No.: US 2026/0090216 A1
(43) Pub. Date: Mar. 26, 2026

(54) DISPLAY PANEL AND DISPLAY APPARATUS

(71) Applicant: SHANGHAI TIANMA MICROELECTRONICS CO., LTD., Shanghai (CN)

(72) Inventors: Xiaoni CHEN, Shanghai (CN); Nan ZHANG, Shanghai (CN); Long CHEN, Shanghai (CN); Bonggeum LEE, Shanghai (CN)

(21) Appl. No.: 19/407,006

(22) Filed: Dec. 3, 2025

(30) Foreign Application Priority Data
Aug. 21, 2025 (CN) 202511179379.1

(51) Int. Cl. H10K 59/122; H10K 59/80

(52) U.S. Cl. CPC H10K 59/122; H10K 59/873

(57) ABSTRACT

Provided are a display panel and a display apparatus. The display panel includes: a substrate; and a pixel definition layer and light-emitting devices located on a side of the substrate. The pixel definition layer has openings. At least a portion of each light-emitting device is located within one opening. The light-emitting device comprise a first electrode, a light-emitting layer, and a second electrode. The first electrode is exposed by the opening. The light-emitting layer is located between the first and second electrodes. The second electrode is located on a side of the light-emitting layer away from the first electrode. The light-emitting layer and the second electrode are at least partially located within the opening and extend to a surface of the pixel definition layer away from the substrate. Light-emitting layers of adjacent light-emitting devices are disconnected from each other. Second electrodes of adjacent light-emitting devices are disconnected from each other.

### CROSS-REFERENCE TO RELATED APPLICATION

The present application claims priority to Chinese Patent Application No. 202511179379.1, filed on Aug. 21, 2025, the content of which is incorporated herein by reference in its entirety.

### TECHNICAL FIELD

The present application relates to the field of display technologies, and in particular, to a display panel and a display apparatus.

### BACKGROUND

Organic Light-Emitting Diode (OLED) is an organic thin-film electroluminescent device. Thanks to its advantages such as simple manufacturing process, low cost, low power consumption, high brightness, wide viewing angle, high contrast ratio, and ability to achieve flexible displays, it has garnered significant attention and been widely applied in electronic display products. In related technologies, the number of times of using high-precision metal masks during the manufacturing of OLED display panels is relatively greater, the cost of the high-precision metal masks is relatively higher, and the aperture ratio of display panels cannot be further improved due to the limitation of the high-precision metal masks. Therefore, reducing the use of high-precision metal masks has been one of the directions of display panel technology development.

### SUMMARY

Embodiments of the present application provide a display panel and a display apparatus to solve the technical problems of reducing the number of uses of high-precision metal masks during manufacturing and reducing manufacturing costs.

In a first aspect, an embodiment of the present application provides a display panel, including: a substrate; and a pixel definition layer and a plurality of light-emitting devices located on a side of the substrate, where the pixel definition layer has openings, and at least a portion of a respective light-emitting device is located within a corresponding opening; the light-emitting device comprise a first electrode, a light-emitting layer, and a second electrode, and the first electrode is exposed by the opening, and the light-emitting layer is located between the first electrode and the second electrode; the second electrode is located on a side of the light-emitting layer away from the first electrode; and the light-emitting layer and the second electrode are at least partially located within the opening and extend to a surface of the pixel definition layer away from the substrate; and light-emitting layers of adjacent light-emitting devices are disconnected from each other, and second electrodes of adjacent light-emitting devices are disconnected from each other.

In a second aspect, based on the same inventive concept, an embodiment of the present application provides a display apparatus, including the display panel according to any embodiment of the present application.

The display panel and the display apparatus provided by the embodiments of the present application have the following beneficial effects: during the fabrication of the display panel provided by the embodiment of the present application, open masks may be used to evaporate the light-emitting layers: first, entire-surface light-emitting layer material and entire-surface second electrode material are fabricated, and then etched to form patterned light-emitting layers and patterned second electrodes. After fabricating the light-emitting layers and the second electrodes of the light-emitting devices of one color, the evaporation and etching steps are then used again to fabricate the light-emitting layers and the second electrodes of the light-emitting devices of another color. After undergoing three evaporation and etching steps, the fabrication of three colors of light-emitting devices over the entire surface can be completed, such that the light-emitting layers of adjacent light-emitting devices are disconnected from each other and the second electrodes of adjacent light-emitting devices are disconnected from each other. The display panel according to the embodiment of the present application does not require the use of high-precision metal masks in the fabrication process of the light-emitting devices, which can reduce the fabrication cost, and can also break through the limitation of high-precision metal masks on the aperture ratio, being conducive to improving the aperture ratio of the display panel.

### BRIEF DESCRIPTION OF DRAWINGS

To more clearly illustrate the technical solutions in the embodiments of the present application or the prior art, a brief description of the accompanying drawings required for describing the embodiments or the prior art will be provided below. Apparently, the accompanying drawings in the following description are some embodiments of the present application, and for those skilled in the art, other accompanying drawings can also be obtained based on these drawings without creative efforts.

FIG. 1 is a schematic diagram of a cross-section of a display panel according to an embodiment of the present application;

FIG. 2 is a schematic diagram of a cross-section of another display panel according to an embodiment of the present application;

FIG. 3 is a schematic diagram of a cross-section of another display panel according to an embodiment of the present application;

FIG. 4 is a schematic diagram of a method for manufacturing a display panel according to an embodiment of the present application;

FIG. 5 is a schematic diagram of a cross-section of another display panel according to an embodiment of the present application;

FIG. 6 is a schematic cross-sectional diagram of another display panel according to an embodiment of the present application;

FIG. 7 is a schematic diagram of a cross-section of another display panel according to an embodiment of the present application;

FIG. 8 is a schematic diagram of a cross-section of another display panel according to an embodiment of the present application;

FIG. 9 is a schematic diagram of a cross-section of another display panel according to an embodiment of the present application;

FIG. 10 is a top view of another display panel according to an embodiment of the present application;

FIG. 11 is a schematic diagram of a cross-section at the position of cutting line A-A′ in FIG. 10;

FIG. 12 is a partial schematic diagram of another display panel according to an embodiment of the present application;

FIG. 13 is a partial schematic diagram of another display panel according to an embodiment of the present application;

FIG. 14 is a partial schematic diagram of another display panel according to an embodiment of the present application;

FIG. 15 is a partial schematic diagram of another display panel according to an embodiment of the present application;

FIG. 16 is a schematic diagram of a cross-section of another display panel according to an embodiment of the present application; and

FIG. 17 is a schematic diagram of a display apparatus according to an embodiment of the present application.

### DESCRIPTION OF EMBODIMENTS

To make the objectives, technical solutions, and advantages of the embodiments of the present application clearer, the technical solutions in the embodiments of the present application will be described clearly and completely below with reference to the accompanying drawings in the embodiments of the present application. Apparently, the described embodiments are some of the embodiments of the present application, rather than all the embodiments. Based on the embodiments of the present application, all other embodiments obtained by a person of ordinary skill in the art without creative efforts shall fall within the protection scope of the present application.

The terms used in the embodiments of the present application are only for the purpose of describing specific embodiments and are not intended to limit the present application. The singular forms “a”, “the”, and “said” used in the embodiments of the present application and the appended claims are also intended to include the plural forms, unless the context clearly indicates otherwise.

In the related art, the number of times high-precision metal masks are used in the manufacturing process of OLED display panels is relatively large. However, the cost of high-precision metal masks is relatively high, and the aperture ratio of the display panel cannot be further improved due to the limitation of the manufacturing process involving high-precision metal masks. For example, during the manufacturing of a display panel, high-precision metal masks are required to be used to evaporate the light-emitting layer of the OLED device. Because in the evaporation process, a certain distance must be maintained between the high-precision metal mask and the substrate to be evaporated, and this distance causes the evaporation material of the light-emitting layer to easily produce a certain offset error after passing through the high-precision metal mask. Such an offset error makes it impossible to further reduce the distance between two adjacent devices while meeting the evaporation yield, which in turn limits the aperture ratio of the display panel.

To solve the above problems, the embodiments of the present application provide a display panel and a display apparatus. During the fabrication of the display panel, an open mask is adopted to evaporate the light-emitting layers of the light-emitting devices; then, the cathodes of the light-emitting devices are formed over the entire surface. The light-emitting layers and the cathodes are etched to retain only the light-emitting layer patterns and cathode patterns at the positions where the light-emitting devices of one color are located. The above evaporation and etching steps are repeated to fabricate the light-emitting devices of the other two colors. No high-precision metal masks need to be used in the fabrication process of the light-emitting devices, which can reduce the fabrication cost and is also conducive to improving the aperture ratio of the display panel. The above is the main technical concept of the present application, and specific embodiments are provided below to illustrate the present application.

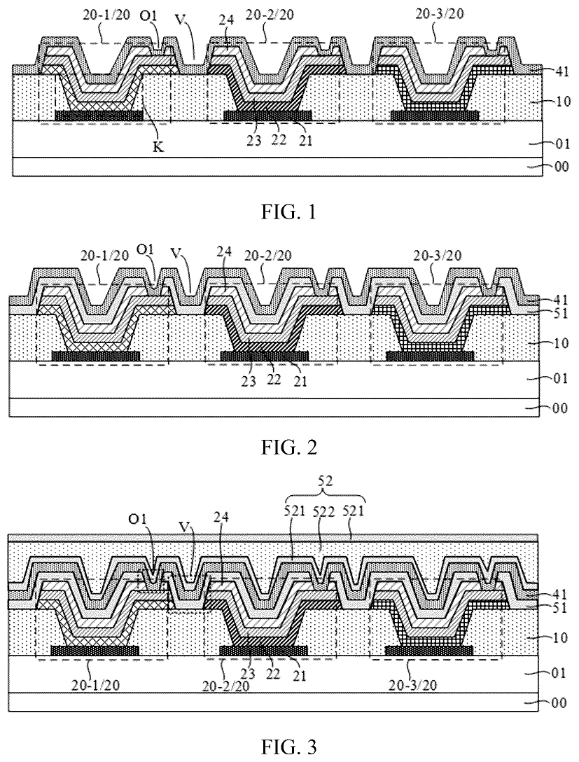

FIG. 1 is a schematic diagram of a cross-section of a display panel according to an embodiment of the present application. As shown in FIG. 1, the display panel includes a substrate 00, and a pixel definition layer 10 and a plurality of light-emitting devices 20 located on a side of the substrate 00; and the pixel definition layer 10 has openings K, and at least a portion of a respective light-emitting device 20 is located within a corresponding opening K. The light-emitting device 20 includes a first light-emitting device 20-1, a second light-emitting device 20-2, and a third light-emitting device 20-3 having mutually different colors; and the first light-emitting device 20-1, the second light-emitting device 20-2, and the third light-emitting device 20-3 are each one of a red light-emitting device, a green light-emitting device, and a blue light-emitting device. A driving layer 01 is provided between the substrate 00 and the light-emitting devices 20, and pixel circuits (not shown in FIG. 1) are arranged in the driving layer 01; and the pixel circuits are configured to drive the light-emitting devices 20 to emit light.

Each light-emitting device 20 includes a first electrode 21, a light-emitting layer 22, and a second electrode 23, the first electrode 21 is exposed by the opening K of the pixel definition layer 10, and the light-emitting layer 22 is located between the first electrode 21 and the second electrode 23. The second electrode 23 is located on a side of the light-emitting layer 22 away from the first electrode 21. One of the first electrode 21 and the second electrode 23 is an anode, and the other is a cathode. For example, the first electrode 21 is an anode, and the second electrode 23 is a cathode. The light-emitting layer 22 includes at least a light-emitting material layer and further includes at least one of an electron transport layer, an electron injection layer, a hole transport layer, and a hole injection layer. The light-emitting layers 22 of the first light-emitting device 20-1, the second light-emitting device 20-2, and the third light-emitting device 20-3 include different light-emitting materials, so that the three light-emitting devices emit light of three colors respectively.

Herein, the light-emitting layer 22 and the second electrode 23 are at least partially located within the opening K and extend to a surface of the pixel definition layer 10 away from the substrate 00. Specifically, the light-emitting layers 22 are in contact with the surface of the pixel definition layer 10 away from the substrate 00. The light-emitting layers 22 of adjacent light-emitting devices 20 are disconnected from each other, and the second electrodes 23 of adjacent light-emitting devices 20 are disconnected from each other. That is, the light-emitting devices 20 have patterned light-emitting layers 22 and patterned second electrodes 23.

For the display panel according to the embodiment of the present application, the light-emitting layers 22 of adjacent light-emitting devices 20 are disconnected from each other, and the second electrodes 23 of adjacent light-emitting devices 20 are disconnected from each other. During the fabrication of the display panel, open masks may be used to evaporate the light-emitting layers 22 of the light-emitting devices 20: first, entire-surface light-emitting layer material and entire-surface second electrode material are fabricated, and then etched to form patterned light-emitting layers 22 and patterned second electrodes 23. After fabricating the light-emitting layers 22 and the second electrodes 23 of the light-emitting devices 20 of one color, the evaporation and etching steps are then used again to fabricate the light-emitting layers 22 and the second electrodes 23 of the light-emitting devices 20 of another color. After undergoing three evaporation and etching steps, the fabrication of three colors of light-emitting devices 20 over the entire surface can be completed, such that the light-emitting layers 22 of adjacent light-emitting devices 20 are disconnected from each other and the second electrodes 23 of adjacent light-emitting devices 20 are disconnected from each other. The display panel according to the embodiment of the present application does not require the use of high-precision metal masks in the fabrication process of the light-emitting devices 20, which can reduce the fabrication cost, and can also break through the limitation of high-precision metal masks on the aperture ratio, being conducive to improving the aperture ratio of the display panel.

In some implementations, as shown in FIG. 1, the display panel further includes a first auxiliary electrode 41, and the first auxiliary electrode 41 is located on a side of the plurality of light-emitting devices 20 away from the substrate 00, where adjacent light-emitting devices 20 are disconnected from each other to form a trench V; it can be understood that each light-emitting device 20 is surrounded by the trenches V. Herein, at least a portion of the first auxiliary electrode 41 is located within the trench V, and the second electrodes 23 of the plurality of light-emitting devices 20 respectively are bonded to the first auxiliary electrode 41. For the display panel according to the embodiment of the present application, after the light-emitting devices 20 are fabricated, the first auxiliary electrode 41 is covered over the light-emitting devices 20, and the second electrodes 23 of the plurality of light-emitting devices 20 respectively are bonded to the first auxiliary electrode 41, thereby realizing the provision of a signal to the plurality of second electrodes 23 via the first auxiliary electrode 41.

Optionally, a material of the first auxiliary electrode 41 includes a transparent conductive material, such as a transparent metal oxide, for example, indium tin oxide or indium zinc oxide. The first auxiliary electrode 41 is fabricated on a light exist side of the light-emitting devices 20; since the first auxiliary electrode 41 is made of a transparent conductive material, the light extraction efficiency of the light-emitting devices 20 can be improved.

In some other implementations, a material of the first auxiliary electrode 41 may further include metals such as titanium or molybdenum.

In some implementations, as shown in FIG. 1, the light-emitting device 20 further includes a protective layer 24, the protective layer 24 is located on a side of the second electrode 23 away from the substrate 00, and the protective layers 24 of adjacent light-emitting devices 20 are disconnected from each other; the second electrodes 23 are bonded to the first auxiliary electrode 41 through first vias O1; along a direction perpendicular to a plane of the substrate 00, the first vias O1 penetrate through at least the protective layers 24. In the embodiment of the present application, the light-emitting devices 20 include patterned protective layers 24; during the fabrication of the display panel, an entire-surface light-emitting layer materials, an entire-surface second electrode material, and an entire-surface protective layer material are fabricated first, and then etched to form the patterned light-emitting layers 22, the patterned second electrodes 23, and the patterned protective layers 24. The protective layers 24 provided on the side of the second electrodes 23 away from the substrate 00 can protect the second electrodes 23 during the etching process, ensuring the electrical performance of the second electrodes 23.

In some implementations, the light-emitting device 20 further includes a light extraction layer, the light extraction layer is located between the protective layer 24 and the second electrode 23, and the light extraction layer can improve the light-exit efficiency of the light-emitting device 20. It can be understood that the light extraction layer in the embodiment of the present application has a patterned structure, and the light extraction layers of adjacent light-emitting devices 20 are disconnected from each other.

In some implementations, FIG. 2 is a schematic diagram of a cross-section of another display panel according to an embodiment of the present application. As shown in FIG. 2, the display panel further includes a first encapsulation layer 51, and the first encapsulation layer 51 is located between the plurality of light-emitting devices 20 and the first auxiliary electrode 41; and the first encapsulation layer 51 at least covers edges of the second electrodes 23 and edges of the light-emitting layers 22. That is, the edges of the second electrodes 23 and the edges of the light-emitting layers 22 exposed at the positions of the trenches V are covered by the first encapsulation layer 51. The second electrodes 23 are bonded to the first auxiliary electrode 41 through the first vias O1, and the first vias O1 at least penetrate through the first encapsulation layer 51 and the protective layer 24. In this embodiment, after the light-emitting devices 20 of three colors are formed, the first encapsulation layer 51 is formed and then the first auxiliary electrode 41 is formed, and the edges of the second electrodes 23 and the edges of the light-emitting layers 22 exposed at the positions of the trenches V formed by adjacent light-emitting devices 20 can be covered by using the first encapsulation layer 51 to protect the light-emitting devices 20, so as to prevent moisture from intruding from the edges of the second electrodes 23, the light-emitting layers 22 and other film layers and from affecting the service life of the light-emitting devices 20.

In addition, the first encapsulation layer 51 covering sidewalls of the trenches V can also play an insulating role between the first auxiliary electrode 41 and the light-emitting layers 22, which can prevent crosstalk between adjacent light-emitting devices 20 and improve the display effect.

Optionally, the first encapsulation layer 51 includes an inorganic material, such as silicon nitride, silicon oxide, and silicon oxynitride.

In some implementations, FIG. 3 is a schematic diagram of a cross-section of another display panel according to an embodiment of the present application. As shown in FIG. 3, the display panel further includes a second encapsulation layer 52, and the second encapsulation layer 52 is located on a side of the first auxiliary electrode 41 away from the substrate 00. The second encapsulation layer 52 includes at least one inorganic encapsulation layer 521 and at least one organic encapsulation layer 522. FIG. 3 is illustrated with the second encapsulation layer 52 including two inorganic encapsulation layers 521 and one organic encapsulation layer 522. In the embodiment of the present application, the second encapsulation layer 52 is formed on the first auxiliary electrode 41, and the second encapsulation layer 52 can protect the light-emitting devices 20 on their light-exit sides, so as to prevent moisture from intruding. The first encapsulation layer 51 and the second encapsulation layer 52 cooperate to protect the light-emitting devices 20 from multiple positions and block intrusion, thereby being capable of effectively improving the service life of the light-emitting devices 20.

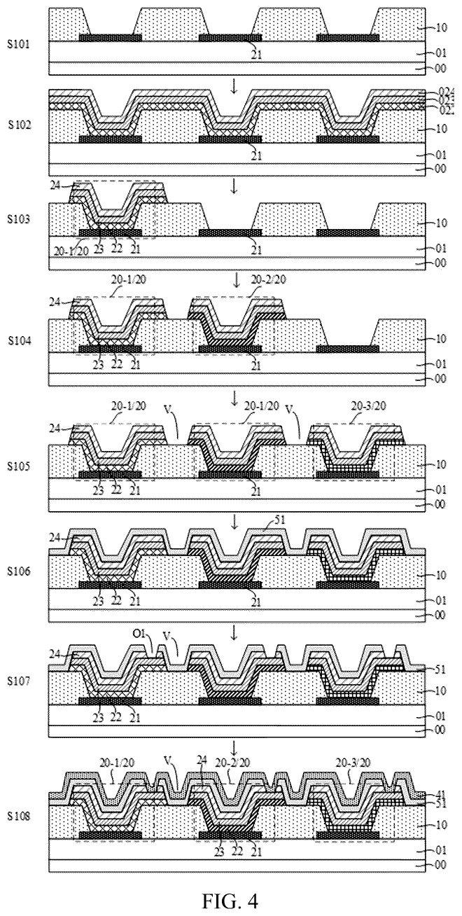

An embodiment of the present application provides a method for manufacturing a display panel, which can be used to manufacture the display panel provided by the embodiments of the present application. FIG. 4 is a schematic diagram of a method for manufacturing a display panel according to an embodiment of the present application. As shown in FIG. 4, the method for manufacturing a display panel includes:

Step S102: forming first electrodes 21 and a pixel definition layer 10, where the first electrodes 21 are located on a side of a driving layer 01 away from a substrate 00. The first electrodes 21 are exposed by openings K of the pixel definition layer 10.

Step S102: forming a light-emitting layer material 022, a second electrode material 023, and a protective layer material 024. Herein, an open mask can be used to form a full-surface light-emitting layer material 022 over the pixel definition layer 10. Then, a full-surface second electrode material 023 and a full-surface protective layer material 024 are formed over the light-emitting layer material 022.

Step S103: etching the light-emitting layer material 022, the second electrode material 023, and the protective layer material 024, and retaining patterns at positions of first light-emitting devices 20-1 to form corresponding light-emitting layers 22, second electrodes 23, and protective layers 24.

Step S104: repeatedly performing the aforementioned Steps S102 and S103 to form light-emitting layers 22, second electrodes 23, and protective layers 24 in second light-emitting devices 20-2.

Step S105: repeatedly performing the aforementioned Steps S102 and S103 to form light-emitting layers 22, second electrodes 23, and protective layers 24 in third light-emitting devices 20-3. It can be seen that the trench V is formed between adjacent light-emitting devices 20, and the light-emitting layers 22 of adjacent light-emitting devices 20 are disconnected from each other, and the second electrodes 23 of adjacent light-emitting devices 20 are disconnected from each other.

Step S106: forming a first encapsulation layer 51, where the first encapsulation layer 51 covers a plurality of light-emitting devices 20.

Step S107: etching film layers above the second electrodes 23 to form first vias 01 exposing the second electrodes 23, where the first vias O1 penetrate through at least the first encapsulation layer 51 and the protective layers 24.

Step S108: forming a first auxiliary electrode 41, and the second electrodes 23 are bonded to the first auxiliary electrode 41 through the first vias O1.

By adopting the manufacturing method provided by the embodiment of the present application, the light-emitting layers 22 and the second electrodes 23 of the light-emitting devices 20 are formed through evaporation and etching processes, and three evaporation and etching processes are performed to form the light-emitting devices 20 of three colors. No high-precision metal mask is required in the manufacture of the light-emitting devices 20, which can reduce the manufacturing cost, break through the limitation of the high-precision metal mask on the aperture ratio, and be conducive to improving the aperture ratio of the display panel.

With reference to the manufacturing method illustrated in FIG. 4, in Step S103, it is necessary to etch the light-emitting layer material 022, the second electrode material 023, and the protective layer material 024. During the process of removing the evaporated light-emitting layer material 022, the etching stops above the pixel definition layer 10. The light-emitting layer material 022 is an organic material, and the pixel definition layer 10 is generally made of an organic material. Therefore, the etching gas used for etching the light-emitting layer material 022 will also produce an etching effect on the surface of the pixel definition layer 10, resulting in relatively severe over-etching of the pixel definition layer 10, thereby producing surface grooves on the pixel definition layer 10 and affecting subsequent film layer evaporation. Moreover, since the side surfaces of the devices are exposed after etching (i.e., at the positions of the trenches V), the organic molecules generated by the over-etching of the pixel definition layer 10 will permeate through the side surfaces of the light-emitting devices 20, leading to device failure. To solve the problems that the pixel definition layer 10 affects subsequent film layer evaporation and the performance of the light-emitting devices 20, an embodiment of the present application further improves the structure of the pixel definition layer 10.

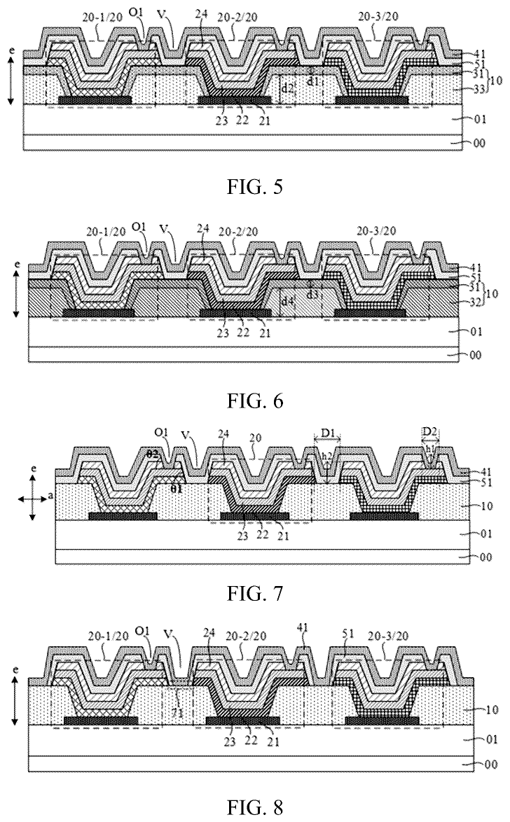

In some implementations, FIG. 5 is a schematic diagram of a cross-section of another display panel according to an embodiment of the present application. As shown in FIG. 5, the pixel definition layer 10 includes a first inorganic layer 31, and the surface of the pixel definition layer 10 away from the substrate 00 is a surface of the first inorganic layer 31. Compared with organic materials, inorganic materials have stronger mechanical properties, and during the process of removing the evaporated light-emitting layer material, the first inorganic layer 31 can achieve an anti-etching effect, thereby avoiding over-etching of the pixel definition layer 10, which can ensure the yield of the subsequent evaporated film layers and also avoid organic molecules from intruding into the light-emitting devices 20, thus improving the manufacturing yield of the display panel. In addition, the compactness of the first inorganic layer 31 is higher, the first inorganic layer 31 can also function to isolate moisture on the side of the light-emitting devices 20 close to the substrate 00, and the collaboration of the first inorganic layer 31 with the first encapsulation layer 51 and the second encapsulation layer 52 can provide tighter protection for the light-emitting devices 20, thereby extending the service life of the light-emitting devices 20.

In some implementations, along a direction e perpendicular to a plane of the substrate 00, a thickness of the pixel definition layer 10 is d, where 0.8 μm≤d≤2.5 μm.

In some implementations, the first inorganic layer 31 includes at least one of silicon oxide, silicon nitride, silicon oxynitride, aluminum oxide, aluminum oxynitride, indium tin oxide, and indium zinc oxide. The first inorganic layer 31 may be an inorganic non-metallic insulating material or a metal oxide. The above-mentioned materials such as silicon oxide, silicon nitride, and silicon oxynitride are commonly used to manufacture insulating layers in display panels, for example, indium tin oxide and indium zinc oxide are commonly used to manufacture conductive layers in display panels. Using the above-mentioned materials to manufacture the first inorganic layer 31 can simplify the process and reduce the cost.

In some implementations, as shown in FIG. 5, the pixel definition layer 10 includes an organic layer 33, and the organic layer 33 is located on a side of the first inorganic layer 31 close to the substrate 00. In this implementation, the pixel definition layer 10 is fabricated by combining organic materials and inorganic materials; the organic layer 33 can be provided with a larger thickness to meet the thickness requirement of the pixel definition layer 10, and the first inorganic layer 31 is utilized to achieve an anti-etching effect during the etching process of the evaporated layers, thereby avoiding over-etching of the pixel definition layer 10 and improving the manufacturing yield of the display panel. Moreover, the first inorganic layer 31 has higher compactness, and the first inorganic layer 31 can also function to isolate moisture on the side of the light-emitting devices 20 close to the substrate 00. The collaboration of the first inorganic layer 31 with the first encapsulation layer 51 and the second encapsulation layer 52 can provide tighter protection for the light-emitting devices 20, thereby extending the service life of the light-emitting devices 20.

In some implementations, as shown in FIG. 5, along a direction e perpendicular to a plane of the substrate 00, a thickness of the first inorganic layer 31 is d1 and a thickness of the organic layer 33 is d2, where d1<d2. The inorganic layer and the organic layer are manufactured by different processes, the thickness of the organic layer 33 is easy to be made thicker, and setting d1<d2 makes the manufacturing process simpler and facilitates meeting the thickness requirement of the pixel definition layer 10.

In some implementations, along a direction e perpendicular to a plane of the substrate 00, a thickness of the first inorganic layer 31 is d1, where 0.3 μm≤d1≤1 μm; and/or, along a direction e perpendicular to a plane of the substrate 00, a thickness of the organic layer 33 is d2, where 0.5 μm≤d2≤1.5 μm. In the embodiment of the present application, the first inorganic layer 31 is used to provide the anti-etching capability for the pixel definition layer 10 during the etching process of the evaporated layers, the thickness of the first inorganic layer 31 does not need to be too large, and setting 0.3 μm≤d1≤1 μm can reduce the manufacturing time of the first inorganic layer 31 on the premise of achieving the anti-etching effect, which is conducive to reducing the manufacturing cost.

In a solution where the organic layer 33 and the first inorganic layer 31 are stacked, the organic layer 33 can function to meet the thickness of the pixel definition layer 10 and reduce the manufacturing time of the pixel definition layer 10. Setting 0.5 μm≤d2≤1.5 μm enables the organic layer 33 to have a relatively large thickness, which can meet the thickness requirement of the pixel definition layer 10, so that the first inorganic layer 31 can be made relatively thinner to save process time.

In some other implementations, FIG. 6 is a schematic diagram of a cross-section of another display panel according to an embodiment of the present application. As shown in FIG. 6, the pixel definition layer 10 further includes at least one second inorganic layer 32, and the second inorganic layer 32 is located on a side of the first inorganic layer 31 close to the substrate 00. FIG. 6 is illustrated with the pixel definition layer 10 including one second inorganic layer 32. In this implementation, the pixel definition layer 10 is entirely fabricated with inorganic materials, and the stacking of the second inorganic layer 32 and the first inorganic layer 31 is utilized to meet the thickness requirement of the pixel definition layer 10, and the first inorganic layer 31 can achieve an anti-etching effect during the etching process of the evaporated layers, thereby avoiding over-etching of the pixel definition layer 10 and improving the manufacturing yield of the display panel.

In some implementations, a dielectric constant of the first inorganic layer 31 is greater than a dielectric constant of the second inorganic layer 32. The larger the dielectric constant of an inorganic material, the higher the compactness of the material after film formation. In this implementation, the dielectric constant of the first inorganic layer 31 is set to be larger, so the first inorganic layer 31 has higher compactness, and thus the first inorganic layer 31 has stronger anti-etching capability during the etching process of the evaporated layers; the pixel definition layer 10 thus has a better anti-etching effect during the etching process of the evaporated layers, thereby avoiding over-etching of the pixel definition layer 10 and improving the manufacturing yield of the display panel.

In some implementations, a material of the first inorganic layer 31 includes silicon nitride, and a material of the second inorganic layer 32 includes silicon oxide. Such a setting enables the dielectric constant of the first inorganic layer 31 to be greater than the dielectric constant of the second inorganic layer 32, and thus the compactness of the first inorganic layer 31 is greater than the compactness of the second inorganic layer 32. In the etching process of the evaporated layers, the first inorganic layer 31 has stronger anti-etching capability, and the pixel definition layer 10 has a better anti-etching effect in the etching process of the evaporated layers, thereby avoiding over-etching of the pixel definition layer 10 and improving the manufacturing yield of the display panel.

In some implementations, as shown in FIG. 6, along a direction e perpendicular to a plane of the substrate 00, a thickness of the first inorganic layer 31 is d3, and a thickness of the second inorganic layer 32 is d4, where d3<d4. The first inorganic layer 31 is used to provide anti-etching capability for the pixel definition layer 10 during the etching process of the evaporated layers; the smaller thickness d3 of the first inorganic layer 31 is conducive to reducing the fabrication time of the first inorganic layer 31. The second inorganic layer 32 has a larger thickness d4, and the stacking of the second inorganic layer 32 and the first inorganic layer 31 can be utilized to meet the thickness requirement of the pixel definition layer 10.

In some implementations, as shown in FIG. 6, along a direction e perpendicular to a plane of the substrate 00, a thickness of the first inorganic layer 31 is d3, where 0.1 μm≤d3≤0.5 μm; and/or, along a direction e perpendicular to a plane of the substrate 00, a thickness of the second inorganic layer 32 is d4, where 0.3 μm≤d4≤1.5 μm.

In the embodiment of the present application, the first inorganic layer 31 is used to provide anti-etching capability for the pixel definition layer 10 during the etching process of the evaporated layers, and the thickness of the first inorganic layer 31 does not need to be too large. Setting 0.1 μm≤d3≤0.5 μm can reduce the fabrication time of the first inorganic layer 31 on the premise of achieving the anti-etching effect, which is conducive to reducing the fabrication cost.

In a solution where the second inorganic layer 32 and the first inorganic layer 31 are stacked, setting 0.3 μm≤d4≤1.5 μm enables the second inorganic layer 32 to have a relatively larger thickness. The stacking of the second inorganic layer 32 and the first inorganic layer 31 can be utilized to meet the thickness requirement of the pixel definition layer 10, so that when the first inorganic layer 31 and the second inorganic layer 32 are made of different inorganic materials, the thickness of the first inorganic layer 31 can be set to be relatively smaller, saving the process time of the first inorganic layer 31 to a certain extent.

In some other implementations, the pixel definition layer 10 includes only the first inorganic layer 31. That is, the pixel definition layer 10 is entirely fabricated with a uniform inorganic material; during the etching process of the evaporated layers, the surface of the first inorganic layer 31 can be utilized to achieve an anti-etching effect, thereby avoiding over-etching of the pixel definition layer 10. Moreover, the pixel definition layer 10 is made of a single material, and the manufacturing process is relatively simple.

In some implementations, FIG. 7 is a schematic diagram of a cross-section of another display panel according to an embodiment of the present application. As shown in FIG. 7, a spacing distance between two second electrodes 23 of two adjacent light-emitting devices 20 is D1, where 2 μm≤D1≤6 μm. As can be seen from FIG. 7, the etching process results in the sidewalls of the second electrodes 23 being inclined surfaces, and the spacing distance D1 between two adjacent second electrodes 23 can be calculated as the minimum distance between the sidewalls of the two second electrodes 23. In the embodiment of the present application, D1≥2 μm is set, enabling the distance between two adjacent light-emitting devices 20 to be sufficiently large to avoid crosstalk between adjacent devices. Meanwhile, D1≤6 μm is set to avoid the distance between two adjacent light-emitting devices 20 being too large, which would affect the device arrangement density.

As shown in FIG. 7, adjacent light-emitting devices 20 are disconnected from each other to form a trench V, and a sidewall of the trench V includes at least a side surface of the light-emitting layer 22 and a side surface of the second electrode 23. An included angle formed between the sidewall of the trench V and a plane of the substrate 00 and pointing to one light-emitting device 20 is a first included angle θ1, where 40°≤θ1≤75°. As can be seen from the method for manufacturing a display panel schematically shown in FIG. 4, the sidewall of the trench V is formed by at least the etching process of the light-emitting layer material and the etching process of the second electrode material. If the first included angle θ1 is too small, the sidewall of the trench V will be too gently inclined, resulting in an excessively long sidewall length in the cross-section, which in turn leads to an excessively large maximum width of the trench V. As can also be seen from FIG. 7, a first via O1 needs to be provided on a side of the trench V close to the light-emitting device 20; if the maximum width of the trench V is too large, it will occupy the area occupied by the light-emitting device 20, which may affect the size of the first via O1. If the first included angle θ1 is too large, the sidewall of the trench V will be too steeply inclined, affecting the thickness of the film layer covering the sidewall. In the embodiment of the present application, 40°≤θ1≤75° is set, so that the inclination degree of the sidewall of the trench Vis neither too small nor too large, which, on one hand, can ensure the arrangement space for the first via O1, and guarantee the bonding yield between the second electrodes 23 and the first auxiliary electrode 41, and on the other hand, can ensure the uniform thickness of the first encapsulation layer 51 covering the sidewall of the trench V, and ensure that the first encapsulation layer 51 can effectively isolate water and oxygen on the side surface of the light-emitting layer 22 and the side surface of the second electrode 23.

In some implementations, as shown in FIG. 7, the second electrodes 23 are bonded to the first auxiliary electrode 41 through first vias O1. Along a direction e perpendicular to a plane of the substrate 00, the first vias 01 overlap with the pixel definition layer 10. That is, the first vias O1 overlap with the relatively flat portions of the second electrodes 23 extending to the side of the pixel definition layer 10 away from the substrate 00, resulting in a higher bonding yield between the second electrodes 23 and the first auxiliary electrode 41, and the bonding positions of the two do not affect the forward light exit of the light-emitting devices 20 (in the direction perpendicular to the plane of the substrate 00).

In some implementations, as shown in FIG. 7, along a first direction a, a width of each first via O1 is D2, where 2 μm≤D2≤56 μm, and the first direction a is parallel to a plane of the substrate 00. In this implementation, D2>2 μm is set to ensure that the size of the first via O1 is sufficiently large, which can reduce the bonding resistance between the second electrode 23 and the first auxiliary electrode 41. Meanwhile, D2≤6 μm is set to ensure that the size of the first via O1 is not too large, avoiding it from occupying excessive space and affecting the arrangement density of the light-emitting devices 20.

As shown in FIG. 7, an included angle formed between an inner wall of a respective first via O1 and a plane of the substrate 00 and pointing to one light-emitting device 20 is a second included angle θ2, where 40°≤θ2≤75°. As can be seen from the method for manufacturing a display panel schematically shown in FIG. 4, the first vias O1 are formed by performing an etching and drilling process on the film layer above the second electrodes 23, and the second included angle θ2 is affected by parameters such as the via depth and via size. If the second included angle θ2 is too small, the inner wall of the first via O1 will be too gently inclined; when the thickness of the film layer above the second electrodes 23 is fixed, the length of the inner wall in the cross-section will be excessively long, which in turn leads to an excessively large maximum width of the first via O1. Since the first vias O1 are used for bonding between the second electrodes 23 and the first auxiliary electrode 41, when the maximum width of the first via O1 is excessively large, it may cause the area occupied by the light-emitting devices 20 to increase, affecting the arrangement density of the light-emitting devices 20. If the second included angle θ2 is too large, it may cause the inner wall of the first via O1 to be too steeply inclined, affecting the uniformity of the film layer covering the inner wall. In the embodiment of the present application, 40°≤θ2≤75° is set, so that the inclination degree of the inner wall of the first via O1 is neither too small nor too large, which, on one hand, can avoid the occupied area of the light-emitting devices 20 being too large and affecting the arrangement density of the light-emitting devices 20, and on the other hand, can ensure the uniform film thickness of the first auxiliary electrode 41 covering the inner wall of the first via O1, and guarantee the bonding yield between the second electrodes 23 and the first auxiliary electrode 41.

In some implementations, as shown in FIG. 7, a depth of a respective first via O1 is h1, and a depth of the trench V is h2, where h2>h1. The trench V is a spacing structure between adjacent light-emitting devices 20 obtained by manufacturing the light-emitting devices 20 using a process that does not require a high-precision mask; the depth of the trench V is related to the number of film layers of the light-emitting devices 20, and the depth h2 of the trench Vis relatively larger. In the embodiment of the present application, h2>h1 is set, that is, the depth h1 of the first via O1 is relatively smaller. Thus, the size of the first via O1 does not need to be set too large to ensure the bonding yield between the second electrodes 23 and the first auxiliary electrode 41, and the relatively smaller size of the first via O1 can also reduce the area of the occupied regions of the light-emitting devices 20, thereby improving the arrangement density of the light-emitting devices 20.

In some implementations, 0.3 μm≤h1≤1 μm; and/or, 0.5 μm≤h2≤2 μm.

The depth h1 of the first via O1 is set to be >0.3 μm, and thus the film layer between the second electrodes 23 and the first auxiliary electrode 41 has a certain thickness, so that the protective layers 24 and the first encapsulation layer 51 can be provided. The protective layers 24 can protect the second electrodes 23 on the front surface of the second electrodes 23 during the process of etching the evaporated layer (such as the light-emitting layer 22), and the first encapsulation layer 51 can encapsulate the side surface of the light-emitting layer 22 and the side surfaces of the second electrodes 23 and isolate moisture intrusion. Setting the depth h1 of the first via O1 to be ≤1 μm means that the size of the first via O1 does not need to be set too large to ensure the bonding yield between the second electrodes 23 and the first auxiliary electrode 41, and the relatively smaller size of the first via O1 can also reduce the area of the occupied regions of the light-emitting devices 20, thereby improving the arrangement density of the light-emitting devices 20.

The depth h2 of the trench V is set to be ≥0.5 μm, so that the depth h2 of the trench Vis sufficiently large to meet the requirement for the number of film layers in the light-emitting device 20. For example, the light-emitting device 20 is provided with a light-emitting layer 22, a second electrode 23, and a protective layer 24; in addition, a light extraction layer can be further provided between the protective layer 24 and the second electrode 23 to improve the light exit efficiency of the light-emitting device 20. In addition, the depth h2 of the trench Vis set to be ≤2 μm, that is the depth h2 of the trench V is not excessively large, which can meet the thinness and lightness of the display panel.

In some implementations, FIG. 8 is a schematic diagram of a cross-section of another display panel according to an embodiment of the present application. As shown in FIG. 8, at the position of the trench V, the first encapsulation layer 51 covers the sidewall of the trench V, and the first encapsulation layer 51 has first hollows 71; along a direction e perpendicular to a plane of the substrate 00, the first hollows 71 at least partially overlap with the trenches V. The first encapsulation layer 51 covers the edges of the second electrodes 23 and the edges of the light-emitting layers 22 exposed by the trenches V, and protects the light-emitting devices 20, preventing moisture from invading through the edges of the second electrodes 23, the light-emitting layer 22 and other film layers, which would affect the service life of the light-emitting devices 20. The first encapsulation layer 51 is made of an inorganic material, and the first hollows 71 formed on the first encapsulation layer 51 can provide stress buffering when the display panel is bent, which is conducive to the flexibility of the display panel.

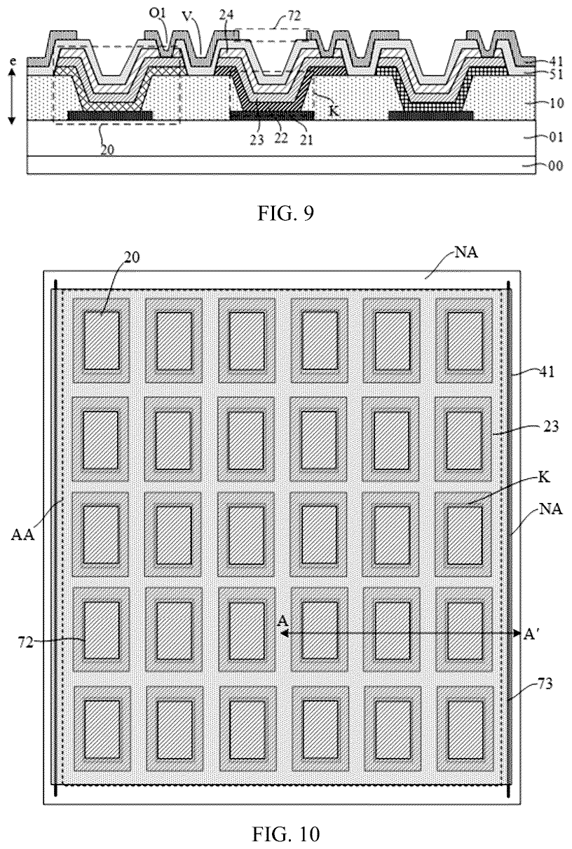

In some other implementations, FIG. 9 is a schematic diagram of a cross-section of another display panel according to an embodiment of the present application. As shown in FIG. 9, the first auxiliary electrode 41 has second hollows 72; and along a direction e perpendicular to a plane of the substrate 00, the second hollows 72 at least partially overlap with the openings K of the pixel definition layer 10. The second electrodes 23 of multiple light-emitting devices 20 are bonded to the first auxiliary electrode 41, and the first auxiliary electrode 41 is used to provide a signal to the second electrodes 23 of the multiple light-emitting devices 20. The first auxiliary electrode 41 is provided on the light-exit side of the light-emitting devices 20, and the second hollows 72 formed on the first auxiliary electrode 41 can improve the light-exit efficiency of the light-emitting devices 20.

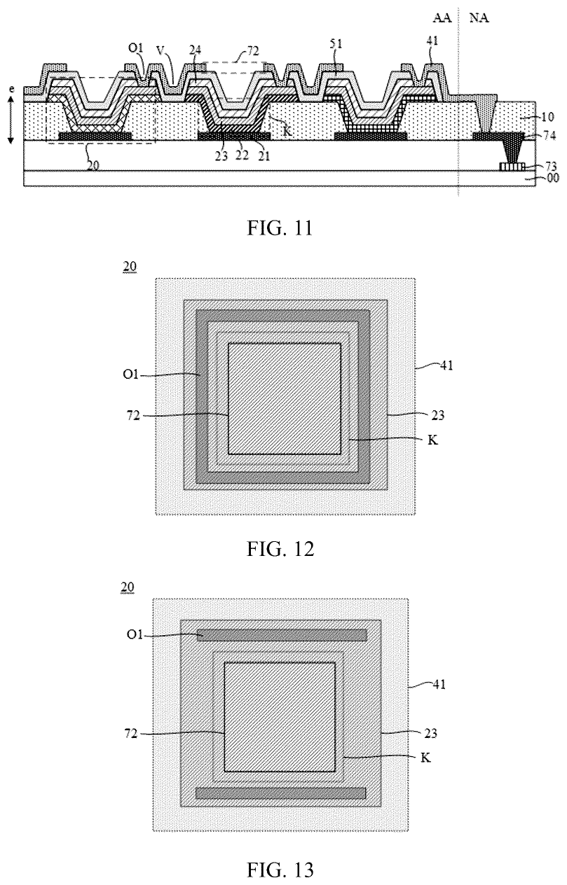

In some implementations, FIG. 10 is a top view of another display panel according to an embodiment of the present application. FIG. 11 is a schematic diagram of a cross-section at the position of cutting line A-A′ in FIG. 10.

As shown in FIG. 10, the display panel includes a display area AA and a non-display area NA, and a plurality of light-emitting devices 20 are arranged in the display area AA. The shape and arrangement of the light-emitting devices 20 in FIG. 10 are merely illustrative and not intended to limit the present application. FIG. 10 only schematically shows the openings K of the pixel definition layer, the second electrodes 23 of the light-emitting devices 20, and the first auxiliary electrode 41. The first auxiliary electrode 41 extends from the display area AA to the non-display area NA, where an electrode signal line 73 is provided; and the first auxiliary electrode 41 are bonded to the electrode signal line 73 in the non-display area NA. As can be seen from FIG. 10, the first auxiliary electrode 41 has the second hollows 72, and the second hollows 72 at least partially overlap with the openings K.

As shown in FIG. 11, the first auxiliary electrode 41 extends from the display area AA to the non-display area NA. The first auxiliary electrode 41 is connected to a transfer electrode 74 through a via-hole penetrating the pixel definition layer 10, and the transfer electrode 74 is connected to the electrode signal line 73 through a via-hole penetrating an insulating layer, thereby achieving the connection between the first auxiliary electrode 41 and the electrode signal line 73. Herein, the transfer electrode 74 and the first electrodes 21 are located in the same layer. The electrode signal line 73 is located in the driving layer; optionally, the electrode signal line 73 and the data lines in the display panel are located in the same layer.

In addition, in the embodiment of the present application, it is set that an orthographic projection of a respective first via O1 onto a plane of the substrate 00 at least partially surrounds an orthographic projection of the opening K onto the plane of the substrate 00. The cross-sectional views of the above embodiments are all schematically shown with the first vias O1 located on one side of the light-emitting devices 20.

In some implementations, FIG. 12 is a partial schematic diagram of another display panel according to an embodiment of the present application. FIG. 12 is a top view illustrating a position of a light-emitting device 20. FIG. 12 illustrates the opening K of the pixel definition layer 10, the second electrode 23, and the first auxiliary electrode 41. It can be understood that the top view direction of the display panel is parallel to a projection direction of the orthographic projection onto the plane of the substrate 00. It can be seen from the top view of FIG. 12 that the orthographic projection of the first via O1 onto the plane of the substrate 00 surrounds the orthographic projection of the opening K onto the plane of the substrate 00. Such a setting can reduce the bonding impedance between the second electrode 23 and the first auxiliary electrode 41, and improve the voltage uniformity on the second electrode 23.

In some other implementations, FIG. 13 is a partial schematic diagram of another display panel according to an embodiment of the present application. It can be seen from the top view of FIG. 13 that an orthographic projection of the first via O1 onto a plane of the substrate 00 partially surrounds an orthographic projection of the opening K onto the plane of the substrate 00.

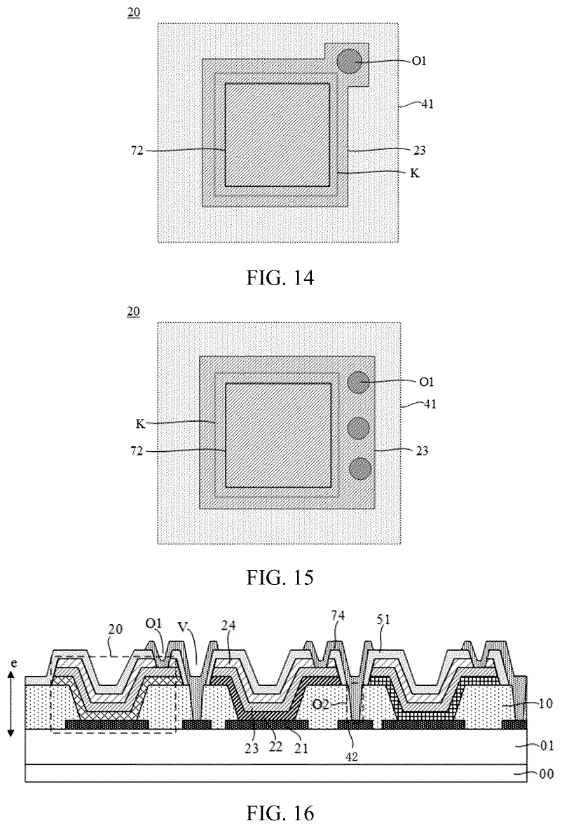

In some other implementations, FIG. 14 is a partial schematic diagram of another display panel according to an embodiment of the present application. It can be seen from the top view of FIG. 14 that an orthographic projection of the first via O1 onto a plane of the substrate 00 is located on a side of an orthographic projection of the opening K onto the plane of the substrate 00, and the second electrode 23 is electrically connected to the first auxiliary electrode 41 through one first via O1. Such a setting can reduce the area occupied by the first via O1, thereby reducing the area occupied by the light-emitting device 20, which can improve the arrangement compactness of the light-emitting devices 20 and increase the arrangement density of the light-emitting devices 20.

FIG. 14 illustrates that the second electrode 23 is electrically connected to the first auxiliary electrode 41 through one first via O1. In some other implementations of the present application, the second electrode 23 may also be electrically connected to the first auxiliary electrode 41 through two or more first vias O1, and the two or more first vias O1 are dispersedly arranged. FIG. 15 is a partial schematic diagram of another display panel according to an embodiment of the present application. It can be seen from the top view of FIG. 15 that an orthographic projection of the first via O1 onto a plane of the substrate 00 is located on one side of an orthographic projection of the opening K onto the plane of the substrate 00, and the second electrode 23 is electrically connected to the first auxiliary electrode 41 through three first vias O1. Such a setting can reduce the bonding impedance between the second electrode 23 and the first auxiliary electrode 41, and improve the voltage uniformity on the second electrode 23.

In some other implementations, FIG. 16 is a schematic diagram of a cross-section of another display panel according to an embodiment of the present application. As shown in FIG. 16, the display panel includes a second auxiliary electrode 42, and the second auxiliary electrode 42 and the first electrode 21 are located in a same layer; adjacent light-emitting devices 20 are separated from each other to form a trench V; along a direction e perpendicular to a plane of the substrate 00, the second auxiliary electrode 42 at least partially overlaps with the trench V; the second electrode 23 is electrically connected to the second auxiliary electrode 42 through a bonding portion 74. In this implementation, the second auxiliary electrode 42 is arranged in the same layer as the first electrode 21, that is, the second auxiliary electrode 42 is routed between adjacent first electrodes 21. Using the second auxiliary electrode 42 to provide a voltage signal to the second electrode 23 can avoid adding an additional film layer on the light-exit side of the light-emitting devices 20, which would affect the light exit efficiency.

As shown in FIG. 16, the pixel definition layer 10 has second vias O2, and the second auxiliary electrode 42 is exposed by the second vias O2; one end of the bonding portion 74 is connected to the second electrode 23, and the other end is connected to the second auxiliary electrode 42 through one second via O2. Herein, the second vias O2 may be formed in the same process as the openings K of the pixel definition layer 10. In the embodiment of the present application, a protective layer 24 and a first encapsulation layer 51 are further formed above the second electrodes 23; the protective layer 24 can protect the surface of the second electrodes 23 during the process of etching to form a film layer such as the light-emitting layer 22, and the first encapsulation layer 51 can cover the edges of the second electrodes 23 and the edges of the light-emitting layers 22 at the positions of the trenches V to prevent moisture intrusion. One end of the bonding portion 74 is electrically connected to the second electrode 23 through the first via O1 penetrating the protective layer 24 and the first encapsulation layer 51. In addition, the bonding portion 74 is connected to the second auxiliary electrode 42 through the second via O2 at the position of the trench V, and the first encapsulation layer 51 covering the sidewalls of the trenches V can also play an insulating role between the bonding portion 74 and the light-emitting layer 22, thereby preventing crosstalk between adjacent light-emitting devices 20 and improving the display effect.

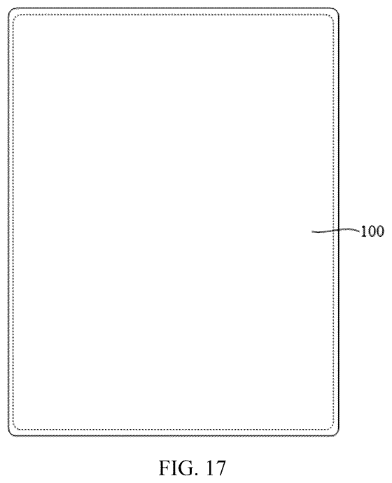

Based on the same inventive concept, an embodiment of the present application further provides a display apparatus, and FIG. 17 is a schematic diagram of a display apparatus according to an embodiment of the present application. As shown in FIG. 17, the display apparatus includes the display panel 100 according to any embodiment of the present application. The structure of the display panel has been described in the above embodiments, and will not be repeated here. The display apparatus according to the embodiment of the present application may be, for example, an electronic device having a display function, such as a mobile phone, a tablet, a computer, a television, and a smart wearable product.

The above are only the preferred embodiments of the present application and are not intended to limit the present application. Within the spirit and principles of the present application, any modification, equivalent replacement, improvement, etc., made thereto shall be included within the protection scope of the present application.

Finally, it should be noted that the above embodiments are only used to illustrate the technical solutions of the present application, but not to limit them; although the present application has been described in detail with reference to the foregoing embodiments, those of skill in the art should understand that they can still modify the technical solutions recited in the foregoing embodiments, or equivalently replace some or all of the technical features thereof; and these modifications or replacements do not cause the essence of the corresponding technical solutions to deviate from the scope of the technical solutions of the embodiments of the present application.

What is claimed is:

1. A display panel, comprising:
a substrate; and
a pixel definition layer and a plurality of light-emitting devices located on a side of the substrate, wherein
the pixel definition layer has openings, and at least a portion of a respective light-emitting device is located within a corresponding opening;
the light-emitting device comprise a first electrode, a light-emitting layer, and a second electrode, and the first electrode is exposed by the opening, and the light-emitting layer is located between the first electrode and the second electrode; the second electrode is located on a side of the light-emitting layer away from the first electrode; and the light-emitting layer and the second electrode are at least partially located within the opening and extend to a surface of the pixel definition layer away from the substrate; and
light-emitting layers of adjacent light-emitting devices are disconnected from each other, and second electrodes of adjacent light-emitting devices are disconnected from each other.

2. The display panel according to claim 1, wherein
the pixel definition layer comprises a first inorganic layer, and the surface of the pixel definition layer away from the substrate is a surface of the first inorganic layer.

3. The display panel according to claim 2, wherein
the pixel definition layer comprises an organic layer, and the organic layer is located on a side of the first inorganic layer close to the substrate.

4. The display panel according to claim 3, wherein
along a direction perpendicular to a plane of the substrate, a thickness of the first inorganic layer is less than a thickness of the organic layer.

5. The display panel according to claim 3, wherein
along a direction perpendicular to a plane of the substrate, a thickness of the first inorganic layer is d1, where 0.3 μm≤d1≤1 μm; and/or,
along a direction perpendicular to a plane of the substrate, a thickness of the organic layer is d2, where 0.5 μm≤d2≤1.5 μm.

6. The display panel according to claim 2, wherein
the pixel definition layer further comprises at least one second inorganic layer, and the second inorganic layer is located on a side of the first inorganic layer close to the substrate.

7. The display panel according to claim 6, wherein
a dielectric constant of the first inorganic layer is greater than a dielectric constant of the second inorganic layer.

8. The display panel according to claim 6, wherein
a material of the first inorganic layer comprises silicon nitride, and a material of the second inorganic layer includes silicon oxide.

9. The display panel according to claim 6, wherein
along a direction perpendicular to a plane of the substrate, a thickness of the first inorganic layer is less than a thickness of the second inorganic layer.

10. The display panel according to claim 6, wherein
along a direction perpendicular to a plane of the substrate, a thickness of the first inorganic layer is d3, where 0.1 μm≤d3≤0.5 μm; and/or
along a direction perpendicular to a plane of the substrate, a thickness of the second inorganic layer is d4, where 0.3 μm≤d4≤1.5 μm.

11. The display panel according to claim 2, wherein
the first inorganic layer includes at least one of silicon oxide, silicon nitride, silicon oxynitride, aluminum oxide, aluminum oxynitride, indium tin oxide, and indium zinc oxide.

12. The display panel according to claim 1, wherein
a spacing distance between two second electrodes of two adjacent light-emitting devices is D1, where 2 μm≤D1≤6 μm.

13. The display panel according to claim 1, wherein
adjacent light-emitting devices are disconnected from each other to form a trench, and a sidewall of the trench comprises at least a side surface of the light-emitting layer and a side surface of the second electrode; and
an included angle formed by the sidewall of the trench and a plane of the substrate and pointing to one light-emitting device is a first included angle θ1, where 40°≤θ1≤75°.

14. The display panel according to claim 1, wherein
the display panel further comprises a first auxiliary electrode, the first auxiliary electrode is located on a side of the plurality of light-emitting devices away from the substrate; adjacent light-emitting devices are disconnected from each other to form a trench, and at least a portion of the first auxiliary electrode is located within the trench; and
the second electrodes of the plurality of light-emitting devices are respectively bonded to the first auxiliary electrode.

15. The display panel according to claim 14, wherein
the display panel further comprises a first encapsulation layer, and the first encapsulation layer is located between the plurality of light-emitting devices and the first auxiliary electrode; and the first encapsulation layer at least covers edges of the second electrodes and edges of the light-emitting layers; and
the second electrodes are bonded to the first auxiliary electrode through first vias, and the first vias at least penetrate through the first encapsulation layer.

16. The display panel according to claim 15, wherein
the first encapsulation layer has first hollows; and
along a direction perpendicular to a plane of the substrate, the first hollows at least partially overlap with the trenches.

17. The display panel according to claim 15, wherein
along a direction perpendicular to a plane of the substrate, the first vias overlap with the pixel definition layer.

18. The display panel according to claim 14, wherein
the first auxiliary electrode has second hollows; and
along a direction perpendicular to a plane of the substrate, the second hollows at least partially overlap with the openings.

19. The display panel according to claim 15, wherein
along a first direction, a width of a respective first via is D2, where 2 μm≤D2≤6 μm, and the first direction is parallel to a plane of the substrate.

20. A display apparatus, comprising a display panel, wherein the display panel comprises:
a substrate; and
a pixel definition layer and a plurality of light-emitting devices located on a side of the substrate, wherein
the pixel definition layer has openings, and at least a portion of a respective light-emitting device is located within a corresponding opening;
the light-emitting device comprise a first electrode, a light-emitting layer, and a second electrode, and the first electrode is exposed by the opening, and the light-emitting layer is located between the first electrode and the second electrode; the second electrode is located on a side of the light-emitting layer away from the first electrode; and the light-emitting layer and the second electrode are at least partially located within the opening and extend to a surface of the pixel definition layer away from the substrate; and
light-emitting layers of adjacent light-emitting devices are disconnected from each other, and second electrodes of adjacent light-emitting devices are disconnected from each other.
